(19) United States
(12) Patent Application Publication
(10) Pub. No.: US 2022/0070344 A1
(43) Pub. Date: Mar. 3, 2022

(54) METHOD OF MANUFACTURING IMAGING MODULE, IMAGING MODULE, AND IMAGING DEVICE

(71) Applicant: Panasonic Intellectual Property Management Co., Ltd., Osaka (JP)

(72) Inventors: Yasutaka MATSUMOTO, Tokyo To (JP); Masayuki YOSHIE, Kanagawa Ken (JP); Eiji NAGASAKI, Osaka Fu (JP)

(73) Assignee: Panasonic Intellectual Property Management Co., Ltd., Osaka (JP)

(21) Appl. No.: 17/369,133

(22) Filed: Jul. 7, 2021

(30) Foreign Application Priority Data
Aug. 27, 2020 (JP) 2020-143614

(51) Int. Cl. H04N 5/225; H05K 5/06; H05K 5/00

(52) U.S. Cl. CPC H04N 5/2257; H05K 5/06; H04N 5/2254; H04N 5/2252; H05K 5/0095

(57) ABSTRACT

A method of manufacturing an imaging module is disclosed. The method includes: producing a housing of the imaging module, the producing including forming a through hole in a part of the housing to connect outer/inner surfaces of the housing; applying an adhesive to the outer surface of the housing in a position where a lens barrel of the imaging module is to be attached, the adhesive having at least a property of being cured by a heat treatment; attaching the lens barrel to the housing with the applied adhesive; curing the adhesive by applying a heat treatment to the housing to which the lens barrel has been attached; and sealing, after the heat treatment, an opening of the through hole with a sealing member such that the opening on the outer surface of the housing is covered by the sealing member.

### CROSS-REFERENCE TO RELATED APPLICATIONS

This application is based upon and claims the benefit of priority from Japanese Patent Application No. 2020-143614, filed on Aug. 27, 2020, the entire contents of which are incorporated herein by reference.

### FIELD

The present disclosure relates generally to a method of manufacturing an imaging module, an imaging module, and an imaging device including the imaging module.

### BACKGROUND

In recent years, with the widespread use of vehicle driving support systems, in-vehicle cameras for driving support are increasingly being installed in vehicles. The in-vehicle camera for driving support plays an important role in the vehicle driving support system such as detecting objects such as vehicles, pedestrians, and obstacles, by image processing performed by an image signal processor (ISP) inside the in-vehicle camera, giving a warning to a driver, and forcibly stopping the vehicle.

In many cases, an imaging module constituting a camera is made by combining a member to which a lens is attached and a housing having therein an imaging element and the like. For example, Japanese Patent Application Laid-open No. 2011-164461 discloses a camera device including an external case and a lens barrel fitted into the external case.

In addition, U.S. Patent Application Publication No. 2012/0019940 discloses a technology of fixing a lens to a front camera housing with an adhesive. More specifically, in U.S. Patent Application Publication No. 2012/0019940, for more firmly assemble the lens and the front camera housing without shifting an optical axis aligned in advance, a technique of curing the adhesive through a two-stage process of UV irradiation and heat treatment is used.

Since the imaging module used in the in-vehicle camera may be broken by vibration during vehicle running, it is necessary to firmly assemble components to one another.

Hence, when the adhesive is thermally cured in order to attach a lens barrel to a housing, it is necessary to apply a heat treatment as in the technology disclosed in U.S. Patent Application Publication No. 2012/0019940. In such a case, air inside the imaging module heated together with the adhesive expands, and thus positive pressure may be generated inside the imaging module. The adhesion strength of the adhesive may deteriorate, and/or the pre-adjusted positional relation between an imaging element and the lens barrel may vary, causing an optical axis shift. As a consequence, the resolution of an image captured by the imaging module is lowered, resulting in the possibility that an object will be erroneously detected when image processing is performed.

### SUMMARY

According to one aspect of the present disclosure, a method of manufacturing an imaging module includes: producing a housing of the imaging module, the housing containing an imaging element and an output mechanism to output image data based on a signal from the imaging element, the producing including forming a through hole in a part of the housing to connect an outer surface of the housing and an inner surface of the housing; applying an adhesive to the outer surface of the housing in a position where a lens barrel of the imaging module is to be attached, the adhesive having at least a property of being cured by a heat treatment; attaching the lens barrel to the housing with the applied adhesive; curing the adhesive by applying a heat treatment to the housing to which the lens barrel has been attached; and sealing, after the heat treatment, an opening of the through hole with a sealing member such that the opening on the outer surface of the housing is covered by the sealing member.

### BRIEF DESCRIPTION OF THE DRAWINGS

FIG. 1 is an exploded view of an imaging module according to an embodiment;

FIG. 2 is a sectional view of the imaging module according to the embodiment;

FIG. 3 is an enlarged sectional view of a rear case including a through hole according to the embodiment;

FIG. 4 is a perspective view of the imaging module according to the embodiment; and

FIGS. 5A to 5E are each a view illustrating a method of assembling the imaging module according to the embodiment.

### DETAILED DESCRIPTION

Embodiment

Hereinafter, an imaging module and a manufacturing method thereof according to the present disclosure will be described with reference to the accompanying drawings.

Configuration of Imaging Module 1

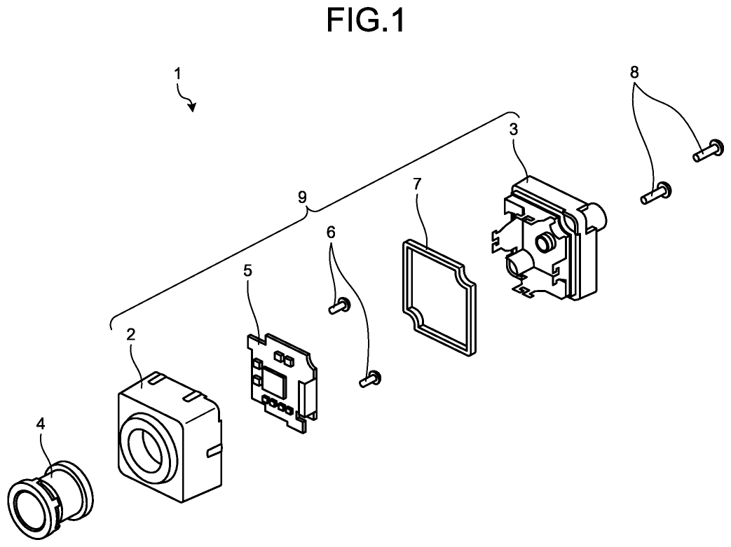

First, the configuration of an imaging module according to an embodiment will be described with reference to FIG. 1 to FIG. 4.

FIG. 1 is an exploded view of an imaging module 1. As illustrated in FIG. 1, the imaging module 1 is composed of a front case 2 (first case), a rear case 3 (second case), a lens barrel 4, a sensor substrate 5, screws 6, a waterproof gasket 7, and screws 8.

The lens barrel 4 is attached to the front case 2 from the outside of the front case 2. The sensor substrate 5 is attached to the inside of the front case 2 by the screws 6. The rear case 3 is attached to the front case 2, to which the sensor substrate 5 is attached, by the screws 8. The waterproof gasket 7 made of rubber is inserted between the front case 2 and the rear case 3 for the purpose of improving a waterproof property. Note that the structure formed by attaching the rear case 3 to the front case 2 is also referred to as a housing part 9 below.

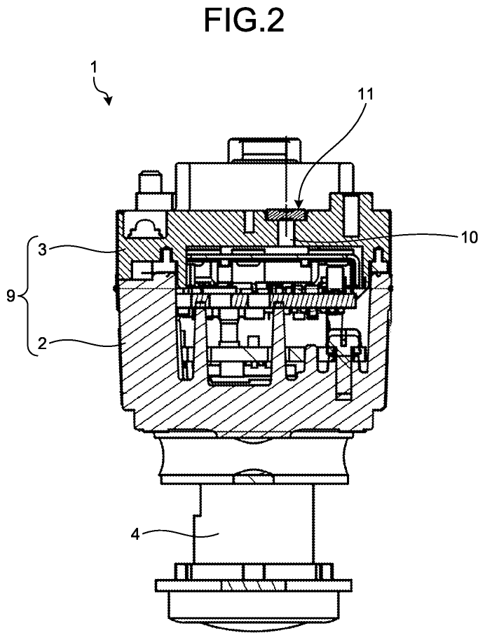

Subsequently, main members constituting the imaging module 1 will be described in more detail with reference to FIG. 2 in addition to FIG. 1. FIG. 2 is a sectional view of the imaging module 1.

Front Case 2

As described above, the lens barrel 4 is attached to the front case 2 from the outside of the front case 2, that is, from a side opposite to the side to which the rear case 3 is attached. It is preferable that a hole having the same shape as that of an end surface of the lens barrel 4 be formed on the surface of the front case 2 to which the lens barrel 4 is attached. By fitting one end of the lens barrel 4 into the hole of the front case 2, the lens barrel 4 is attached to the front case 2. At the time of the fitting, an adhesive for fixing the lens barrel 4 is applied to a peripheral edge of the hole of the front case 2 and the surface of the front case 2 with which the end surface of the lens barrel 4 comes into contact.

Hereinafter, the adhesive to be applied will be described. The adhesive that fixes the front case 2 and the lens barrel 4 has at least a property of being cured by a heat treatment (a thermosetting property). For attaching the front case 2 and the lens barrel 4 with higher accuracy, it is preferable that the adhesive also has a property of being temporarily cured by ultraviolet (UV) irradiation or the like before the main curing by the heat treatment. Hereinafter, the temporary curing by the UV irradiation is referred to as “first curing” and the main curing by the heat treatment is referred to as “second curing”. Accordingly, it is preferable that the adhesive used in the present embodiment be cured through a two-stage process of the first curing by the UV irradiation and the second curing by the heat treatment. Examples of the adhesive cured through such through a two-stage process may include an adhesive containing an epoxy resin, and the like.

By performing the first curing by the UV irradiation beforehand, it is capable of preventing the lens barrel 4 attached to the housing part 9 from positional shifting before the second curing by the heat treatment. As the material of the front case 2, a resin, a metal, or the like can be used. From the viewpoint of moldability, it is preferably made of a resin, and from the viewpoint of heat dissipation, it is preferably made of a metal.

Rear Case 3

The rear case 3 includes an output mechanism of outputting an image signal. Examples of the output mechanism may include a coaxial (two-wire-type) connector, an STQ (four-wire-type) connector, a CAN-containing STQ (six-wire-type) connector, and the like.

As illustrated in FIG. 2, the rear case 3 is attached to the front case 2 to form the housing part 9. A through hole 10 is formed in the rear case 3. The through hole 10 connects an internal space of the housing part 9 and a space outside the housing part 9.

As the material of the rear case 3, a resin, a metal, or the like can be used. Like the front case 2, from the viewpoint of moldability, the rear case 3 is preferably made of a resin, and from the viewpoint of heat dissipation, the rear case 3 is preferably made of a metal. In such a case, the front case 2 and the rear case 3 may be made of the same material or may be made of different materials.

Lens Barrel 4

The lens barrel 4 containing lenses is a cylindrical member that is attached to the front case 2 with the adhesive. The lenses in the lens barrel 4 are made of plastic, glass, or the like, to form an image of light from an object on an imaging element to be described later.

Sensor Substrate 5

The sensor substrate 5 is a substrate on which the imaging element is mounted. The imaging element converts light having passed through the lens in the lens barrel 4 into an electric signal. The sensor substrate 5 is provided with holes through which the screws 6 pass. The sensor substrate 5 is fixed to the front case 2 by the screws 6 through the holes.

Waterproof Gasket 7

The waterproof gasket 7 is a sealing member for maintaining the airtightness of the internal space of the housing part 9. The waterproof gasket 7 is interposed between the front case 2 and the rear case 3, and is pressed from both sides. As a consequence, the waterproof gasket 7 seals the mating surface of the front case 2 and the rear case 3, so that the imaging module 1 possesses a waterproof property.

As the material of the waterproof gasket 7, any elastic material such as rubber can be used.

Through Hole 10

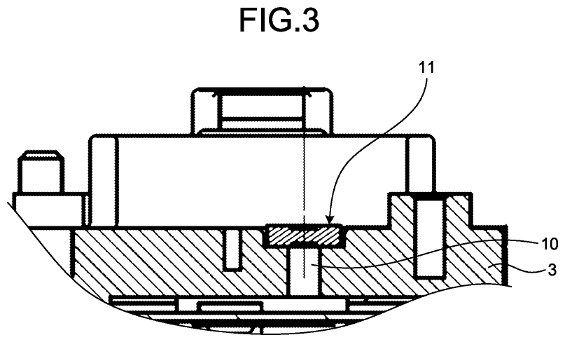

The through hole 10 will be described with reference to FIG. 3. FIG. 3 is an enlarged sectional view of the rear case 3 including the through hole 10.

The through hole 10 is provided for discharging air in the internal space of the housing part 9, which has been heated by thermally curing the adhesive, to the outside of the housing part 9. As illustrated in FIG. 3, when the manufacturing of the imaging module 1 is completed, an opening of the through hole 10 seen from the outside is sealed by a sealing member 11.

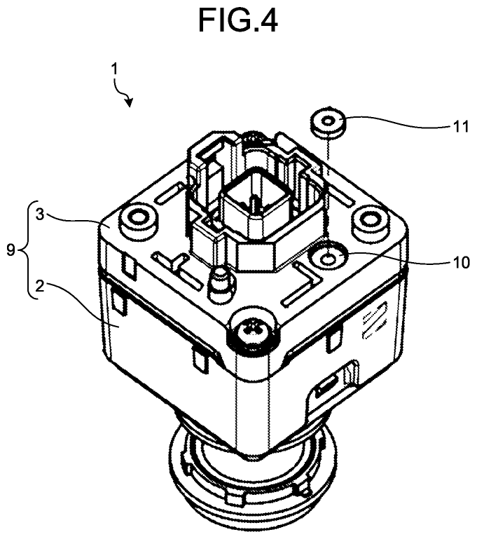

The through hole 10 will be described in more detail below with reference to FIG. 4. FIG. 4 is a perspective view of the imaging module 1.

As illustrated in FIG. 4, the through hole 10 is formed on a wall surface of the rear case 3. The shape of the through hole 10 is not particularly limited as long as it is sufficient for discharging air from the housing part 9. Furthermore, the number of through holes 10 is also not particularly limited as long as it is sufficient for discharging air from the housing part 9. Furthermore, in the present embodiment, the through hole 10 is formed in the rear case 3, but it may be formed in the front case. Note that, from the view of practicality, the through hole 10 is preferably formed at a position where the sealing member 11 for closing the through hole 10 does not obstruct the mounting of the imaging module 1 on a camera device (not illustrated).

Sealing Member 11

The sealing member 11 is attached to seal the opening of the through hole 10 in the external space. The sealing member 11 is adhered to the rear case 3 by an optional method. Details of the adhering method of the sealing member 11 will be described in detail later.

The material of the sealing member 11 can be variously selected depending on the adhering method of the sealing member 11. For example, when the sealing member 11 is adhered by laser welding, it is preferable to use a laser-transmitting resin for the material of the sealing member 11.

Manufacturing Method of Imaging Module 1

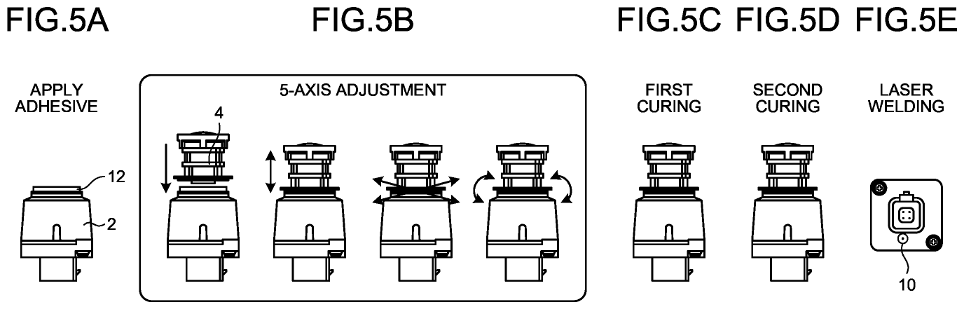

Next, the manufacturing method of the imaging module 1 will be described below with reference to FIG. 5.

The manufacturing method of the imaging module 1 includes the following steps of producing the housing part 9, attaching the lens barrel 4, curing the adhesive, and sealing the through hole 10.

Producing of Housing Part 9

Among the constituent members of the imaging module 1, the housing part 9 is first produced (the producing step is not illustrated in FIG. 5). The producing step of the housing part 9 includes a sub-step of forming the through hole 10 in the rear case 3 as illustrated in FIGS. 2 and 3.

The sensor substrate 5 is attached and fixed to the front case 2 by using the screws 6. After that, the front case 2 and the rear case 3 are connected by using the screws 8 while interposing the waterproof gasket 7 between the front case 2 and the rear case 3. The housing part 9 is produced in this way.

Attaching of Lens Barrel 4

As illustrated in FIG. 5A, an adhesive is applied to the attachment position of the lens barrel 4 (a position where the lens barrel 4 is to be attached) on the front case 2 to form an adhesive layer 12.

Subsequently, the lens barrel 4 is attached to the housing part 9 by performing, using a 5-axis adjuster, a 5-axes adjustment including an optical axis adjustment (X/Y), a focus position (Z), and a tilt (θX/θY) of the imaging module while monitoring an image output by the output mechanism of the rear case 3. More specifically, as illustrated in FIG. 5B, the front case 2, on which the adhesive layer 12 has been formed, and the lens barrel 4 are brought close to each other to a predetermined distance. Next, the lens barrel 4 is shifted in the Z-axis direction (an optical axis direction of the lens) while searching the optical axis, the center, and the periphery for a peak of a modulation transfer function (MTF), thereby determining an adjustment position from a calculated value (adjustment of the focus position). Next, the optical axis is adjusted by performing a positional correction in the XY direction (a direction orthogonal to the optical axis direction of the lens). Next, the tilt (θX/θY) adjustment is performed by tilting the position of the imaging element with respect to the optical axis direction of the lens. Note that the order of the optical axis adjustment is not limited to the aforementioned order. Furthermore, the parameters used for the optical axis adjustment are not limited to the 5 axes.

Curing of Adhesive

After the 5-axis adjustment above is completed, the adhesive is cured through a two-stage process to fix the lens barrel 4 to the front case 2. Specifically, the adhesive is cured through the two-stage process of the first curing using the UV irradiation and the second curing using the heat treatment.

More specifically, as illustrated in FIG. 5C, the UV irradiation is performed on the adhesive which has been applied to the attachment portion between the front case 2 and the lens barrel 4. With this process, the positional relation between the imaging element and the lens barrel 4, which is adjusted in advance, is temporarily fixed. Next, as illustrated in FIG. 5D, the second curing is performed by applying the heat treatment to the adhesive subjected to the first curing. In general, it is desirable that the heat treatment be applied for five minutes or longer in a heating device heated to 70° C. or higher. With this process, the lens barrel 4 is more rigidly assembled to the front case 2. By the two-stage curing of the adhesive described above, the imaging module 1 is able to secure strength to withstand an impact received during vehicle running without shifting the optical axis aligned in advance.

In the imaging module 1, the thermally expanded air in the internal space of the housing part 9 is discharged to an exterior through the through hole 10 formed in the rear case 3. Therefore, increase in pressure within the internal space of the housing part 9 is suppressed.

Sealing of Through Hole 10

As illustrated in FIG. 5E, after the second curing of the adhesive by the heat treatment is completed, the sealing member 11 is attached to cover the opening of the through hole 10, and is laser-welded to the rear case 3. With this process, the through hole 10 is sealed and the housing part 9 is made airtight.

With the processes described above, the manufacturing method of the imaging module 1 of the embodiment is finished.

As mentioned above, during the second curing of the adhesive by the heat treatment, air in the internal space of the housing part 9 thermally expands. In a case that the heat treatment is applied without the through hole 10, pressure may be applied to the internal space of the airtight housing part 9. As a result, the adhesive strength of the adhesive may be lowered. In addition, the pre-adjusted positional relation between the imaging element and the lens barrel 4 may shift, thereby causing an optical axis shift.

In contrast, according to the manufacturing method of the imaging module 1, during the second curing of the adhesive by the heat treatment, thermally expanded air in the internal space of the housing part 9 is discharged through the through hole 10. Therefore, it is capable of avoiding the generation of positive pressure inside the housing part 9 of the imaging module 1, so that the deterioration in adhesive strength and the shifting of an optical axis during thermal curing are prevented.

Moreover, by sealing the through hole 10 after the heat treatment is completed, the imaging module 1 possesses the waterproof property.

When the sealing of the through hole 10 is performed by laser welding, the through hole 10 can be sealed in a short time and the sealing member 11 can be attached to the rear case 3 with high mechanical strength.

Modification of Manufacturing Method of Imaging Module 1

In the foregoing manufacturing method of the imaging module 1, the through hole 10 is sealed by performing the laser welding of the sealing member 11. The method of sealing the through hole 10 is not limited only to the laser welding.

Sealing methods other than the laser welding will be described below.

For example, an adhesive may be used as the sealing member 11. More specifically, an adhesive is poured into the through hole 10 from the external space of the imaging module 1 and is cured, thereby sealing the through hole 10. At this time, the opening of the through hole 10 in the external space is sealed with the adhesive including a material different from that of the rear case 3. In the method of sealing the through hole 10 by the adhesive, work is simplified as it is not necessary to use a separate member as the sealing member 11.

For another example, a portion to be used as a material for the sealing member 11 may be provided near the through hole 10 and be subjected to thermocompression bonding, thereby sealing the through hole 10. More specifically, the sealing member 11 including the same material as that of the rear case 3 is pressed by using a soldering iron heated at 250° C. to 300° C., and is deformed to close the opening of the through hole 10 seen from the external space. In the method of sealing the through hole 10 by the thermocompression bonding, it does not require a separate member such as the sealing member 11 and simultaneously the through hole 10 can be sealed with the same material as that of the rear case 3 with the through hole 10 formed.

An imaging device including the imaging module according to the present disclosure is also included in the scope of the invention. Examples of the imaging device herein may include a camera, a vehicle component, an in-vehicle device on which the imaging module is installed, etc.

Moreover, the camera including the imaging module according to the present disclosure may be, for example, an in-vehicle camera, a security camera, a drone camera, etc.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A method of manufacturing an imaging module, the method comprising:
producing a housing of the imaging module, the housing containing an imaging element and an output mechanism to output image data based on a signal from the imaging element, the producing including forming a through hole in a part of the housing to connect an outer surface of the housing and an inner surface of the housing;
applying an adhesive to the outer surface of the housing in a position where a lens barrel of the imaging module is to be attached, the adhesive having at least a property of being cured by a heat treatment;
attaching the lens barrel to the housing with the applied adhesive;
curing the adhesive by applying a heat treatment to the housing to which the lens barrel has been attached; and
sealing, after the heat treatment, an opening of the through hole with a sealing member such that the opening on the outer surface of the housing is covered by the sealing member.

2. The method according to claim 1, wherein the sealing is executed by applying laser welding to the sealing member consisting of a laser-transmitting resin.

3. The method according to claim 1, wherein the sealing is executed by pouring the sealing member into the through hole from an exterior of the imaging module, the sealing member being a sealing material for sealing the through hole by solidifying.

4. The method according to claim 1, wherein the sealing is executed by applying thermocompression bonding to the sealing member provided near the through hole in the housing, the thermocompression bonding being applied such that the through hole is covered with the sealing member.

5. The method according to claim 1, wherein the attaching of the lens barrel to the housing includes curing the adhesive by irradiating the adhesive with ultraviolet rays.

6. The method according to claim 1, wherein the heat treatment is applied by putting the housing into a device heated to 70° C. or higher, for five minutes or longer.

7. The method according to claim 1, wherein the producing of the housing is executed by connecting a first case and a second case while interposing a gasket between the first case and the second case, the first case containing the imaging element, the second case containing the output mechanism.

8. The method according to claim 7, wherein the through hole is formed in the second case.

9. An imaging module comprising:
a lens barrel containing lenses;
a housing to which the lens barrel is attached with a thermosetting adhesive, the housing containing an imaging element and an output mechanism to output image data based on a signal from the imaging element;
a through hole provided in a part of the housing to connect an outer surface of the housing and an inner surface of the housing; and
a sealing member to seal an opening of the through hole on the outer surface of the housing.

10. An imaging device comprising the imaging module according to claim 9.
